(19) United States
(12) Patent Application Publication
(10) Pub. No.: US 2007/0237978 A1
(43) Pub. Date: Oct. 11, 2007

(54) FUNCTIONAL DIRECT COATING OF AN ALUMINIUM FOIL

(75) Inventor: Gunter SCHUBERT, Rheinbach (DE)

Correspondence Address: PROSKAUER ROSE LLP;PATENT DEPARTMENT, 1585 BROADWAY, NEW YORK, NY, 10036-8299, US

(73) Assignee: HYDRO ALUMINIUM DEUTSCHLAND GMBH, Koln (DE)

(21) Appl. No.: 11/689,981

(22) Filed: Mar. 22, 2007

(30) Foreign Application Priority Data
Mar. 23, 2006 (DE) 10 2006 013 869.4
Jun. 6, 2006 (DE) 10 2006 026 575.0

(51) Int. Cl. B21C 37/00; C23C 14/56; B05D 1/00; B05D 3/12; B05D 3/00

(52) U.S. Cl. 428/607; 427/178; 427/209; 427/289; 427/398.2

(57) ABSTRACT

A method of manufacturing a coated aluminium foil wherein the aluminium foil is manufactured from a hot strip or a cast strip of aluminium or an aluminium alloy by cold-rolling with or without intermediate annealing and coiled onto a coil, while optional annealing of the aluminium foil takes place prior coiling, includes one or two side coating of the aluminium foil with a functional coating. The object of providing a method of manufacturing a coated aluminium foil with which the manufacturing costs of the coated aluminium foil can be lowered is solved according to the invention in that prior to coiling, more preferably before the optional annealing of the aluminium foil, one or two-sided coating of the aluminium foil with a functional coating takes place.

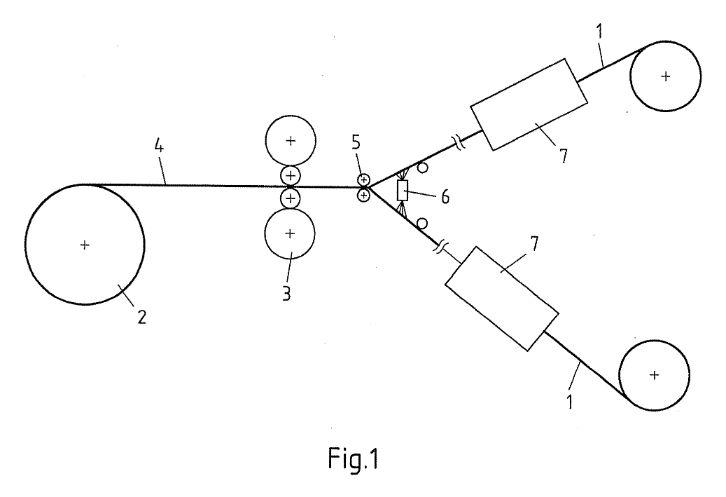

The invention relates to a method of manufacturing a coated aluminium foil wherein the aluminium foil is manufactured from a hot strip or cast strip of aluminium or an aluminium alloy by cold rolling with or without process annealing and coiled onto a coil, wherein as an option annealing of the aluminium foil takes place prior coiling. The invention further relates to an aluminium foil of aluminium or an aluminium alloy with a functional coating as well as to an advantageous use of the aluminium foil.

Currently aluminium foils are manufactured in that initially a slab of aluminium or an aluminium alloy is cast, the slab is hot-rolled into hot strip and the hot-rolled strip is subsequently cold-rolled to the final thickness of the aluminium foil by cold rolling with or without intermediate annealing or from a cast strip through cold rolling with possible heat treatment. In the process, the slab can be subjected to heat treatment or homogenisation before the hot rolling as an option. To achieve preferably low thicknesses of the aluminium foil the aluminium foil is preferably cold-rolled doubled and de-doubled again before coiling onto a coil. Following cold rolling or de-doubling the aluminium foil is generally edged, cut to size and coiled into a coil. During the further processing the aluminium foil manufactured in this way is then unwound again and subjected to pre-treatment. The pre-treatment for example is a baked lacquering, a priming or a conversion treatment of the aluminium foil. During the conversion treatment a barrier and/or adhesive layer is formed through chemical reaction on the surface which is crystalline or amorphous, which for example protects against corrosion and/or enables better lacquer adhesion. Since the speeds during the further processing of the aluminium foil, the so-called “Refiner foil” for example during the manufacture of sterilisable means of packaging is often greater than during the pre-treatment of the aluminium foils, the aluminium foil is coiled onto a coil again after the pre-treatment and the coil passed on for further processing thereafter. The differences of the processing speed are even greater when using self-organising molecules as functional coating of the aluminium foil since the self-organisation of the molecules is only incomplete at high strip speeds.

Departing from the prior art as described before the present invention has the object to provide a method for manufacturing of a coated aluminium foil by means of which the manufacturing costs for products, more preferably sterilisable composite or packaging means, consisting of a coated aluminium foil, can be lowered. In addition to this, the invention has the object to propose a corresponding aluminium foil or an advantageous usage of the aluminium foil.

According to a first teaching of the present invention the above mentioned object for a method according to the preamble of the claim, is solved in that prior to coiling, more preferably prior to the optional annealing of the aluminium foil, single or double-sided coating of the aluminium foil with a functional coating takes place.

Since, according to the invention, single or double-sided coating of the aluminium foil with a functional coating takes place even during the manufacture of the aluminium foil the required unwinding and coiling processes of the aluminium foil required during further processing for applying functional coatings can be avoided and the manufacturing costs for products with coated aluminium foils reduced. The single or double-sided functional coating of the aluminium foil can be adapted to the further processing of the aluminium foil for example into a sterilisable composite or packaging means, and may ensures a wide range of functions.

Coated aluminium foils with a particularly low thickness can be made available in a simple manner according to a next further-developed embodiment of the method according to the invention in that the aluminium foil is doubled during cold rolling and the application of the functional coating takes place during or after the de-doubling of the aluminium foils.

If the aluminium foil is edged and cut to size before the coiling, while during edging or cutting of the aluminium foil the functional coating of the aluminium foil is applied, existing plants can be used for the arrangement of means for coating of the aluminium foil can be used and investment costs saved. Merely an application device for the functional coating is additionally required.

A particularly simple possibility of coating the aluminium foil on one or two sides is achieved according to a next further-developed embodiment of the method according to the invention in that the functional coating is applied making use of a solvent, more preferably a rolling oil and, prior to coiling of the aluminium foil, at least one heat treatment of the aluminium foil for removal of the solvent, more preferably the rolling oil, takes place. The use of rolling oil is particularly advantageous since the rolling oil is already used during cold rolling. This results in an easy wetting of the surface of the aluminium foil during applying the functional coating and thus in even coating. To avoid wetting problems during coating the solvents used should preferably be compatible with rolling oil so that as high as possible a wetting ratio is achieved. However, it is also conceivable that the functional coating takes place after the annealing of the aluminium foil wherein the aluminium foil after the annealing generally hardly has any rolling oil residue. In this case therefore almost any solvent can be used.

The functional coating of the aluminium foil is preferably applied using a spray or roller applicator. Through the arrangement of several nozzles on a spray beam the spray applicator enables a flexible adaptation of the coating widths to the corresponding width of the aluminium foil. With the roller applicator the coating of the aluminium foil takes place by rolling, while the application quantity is dependent on the selected engraving, grid, roughness and the speed of the roller relative to the foil. Consequently the amount of application for the functional coating can be controlled very accurately.

The method according to the invention is particularly advantageous if the aluminium foil has a thickness from 2 to 100 μm since aluminium foils with that thickness are commonly used in coated form for the manufacture of packaging means.

According to a next further-developed embodiment of the method according to the invention, a functional coating with adhesion-supporting, release, corrosion protection and/or wetting-supporting characteristics is applied. These typical characteristics of functional coatings are frequently required during the manufacture of packaging means for example to protect the aluminium foil from corrosion through the effects of the filled product. The adhesion-supporting characteristic for example ensures that plastic foils coated onto the aluminium foil, adhesives, paints or printing inks adhere particularly well to the aluminium foil surface. Coatings with wetting-supporting characteristics are preferably used when during the application of a fluid on the aluminium foil, for example a liquid lacquer, the wetting characteristics of the aluminium foil have to be improved for example to achieve an almost complete wetting and adhesion. Release characteristics in contrast prevent wetting or contamination of the foil. In addition to this, other functional coatings are also conceivable.

Preferably the functional characteristic of the coating, more preferably the adhesion-supporting characteristic and/or the wetting-supporting characteristic can be subsequently activated, for example by a flame, plasma or corona treatment. In this way it can be ensured that the relevant characteristics of the aluminium foil are provided only once these are required during the manufacturing process, for example the adhesion-supporting characteristics shortly before the application of another material on the aluminium foil surface.

Particularly good characteristics in terms of corrosion protection, adhesion-support or wettability can be achieved in that according to a next advantageous embodiment of the method according to the invention, by the functional coating a graft layer is formed, in particular consisting of self-organising molecules, preferably consisting of phosphonic acids, carbonic acids or their compounds or silanes. With a graft layer, the head groups of the adsorbing molecule interact with the substrate, i.e. here with the layers of the aluminium foil near the surface. Because of this interaction the head molecules on the surface are pushed closer together so that now the middle parts of the molecules used can react with one another. Because of Van-der-Waals forces, these additionally bring about tight packing of the graft layer to the aluminium surface. For example as a result of this tight packing of the molecules deposited on the surface of the aluminium foil, dissolution of the aluminium oxide layer formed on the surface of the aluminium foil can be prevented since other compounds are kept away or displaced from the aluminium surface so that good corrosion protection is achieved. The covalent, ionic-covalent or polar bonds to the aluminium oxide surface of the aluminium foil that are formed can be utilized in an easy manner to form an adhesion-supporting agent that can be activated. Upon activation of the adhesion-supporting agent reactive groups are formed at the ends of the molecules of the graft layer facing away from the surface of the aluminium foil, for example through corona treatment, which for example form particularly strong compounds with a plastic melt. Phosphonic acids, sulfonic acids and carbonic acids are generally used to form corrosion protection. Silanes in contrast are typically used for forming an adhesion-supporting layer.

If substituted, phosphonic acids or their derivatives, more preferably diglyceride-phosphonate, alkylendiphosphonate or alkoxysilane are used to form the graft layer, a wetting-supporting agent, a corrosion protection and an adhesion-supporting agent can be made available through the functional coating through diglyceride-phosphonate, alkylendiphosphonate and alkoxysilane respectively.

According to a second teaching of the present invention the above mentioned object is solved by an aluminium foil of aluminium or an aluminium alloy with a functional coating which is manufactured through the method according to the invention. As already explained above, the aluminium foil manufactured according to the invention can be used without additional unwinding, surface treatment and coiling, for further processing, for example to manufacture a packaging means so that the manufacturing costs of the packaging means can be lowered.

The use of the aluminium foil according to a third teaching of the present invention for manufacturing of composite materials, more preferably sterilisable composite materials or sterilisable packaging means is therefore advantageous. On the one hand the functional coating even when employing increased temperatures as occur during sterilising ensures that adequate adhesion is maintained between the aluminium foil and the material intended for contact with the filled product. On the other hand additional process steps during further processing are avoided with the functional coating coated immediately after or during manufacturing of the aluminium foil. As a result, particularly low manufacturing costs for composite materials, for example sterilisable composite materials or sterilisable packaging means can be achieved when using an aluminium foil manufactured according to the invention.

There are a plurality of possibilities of further developing and forming the method according to the invention and the aluminium foil according to the invention or its usage. To this end, reference is made on the one hand to the patent claims subordinate to patent claim 1 and to the description of an exemplary embodiment of the method according to the invention in connection with the drawing.

The only FIGURE shows a schematic view of the processing steps during the manufacture of an aluminium foil 1 according to the invention. Not shown in the FIGURE is that the doubled aluminium foil 4 was previously manufactured from a hot strip which was hot-rolled from a slab of an aluminium alloy manufactured through cold rolling with or without process annealing and coiled onto the coil 2 in doubled form.

According to the Figure the doubled aluminium foil 4 is initially unwound from a coil 2, cold-rolled using a cold rolling stand 3 and subsequently de-doubled. The doubled aluminium foil 4 passes through the cold rolling stand 3 and is thus cold-rolled to a minimal final dimension, for example 2 to 7 μm. Following cold rolling of the doubled aluminium foil 4 the doubled aluminium foil 4 is de-doubled at the guide rollers 5 and divided into two single aluminium foils 1. After de-doubling the functional coating is effected by the spray applicator 6 which in the exemplary embodiment of the method according to the invention shown is performed immediately after de-doubling.

For the functional coating, rolling oil is preferably used as solvent which during cold rolling is present on the aluminium strip and insofar enables good wettability of the surface of the aluminium foil 1. Here, it is conceivable to use the rolling oil as solvent for the functional coating directly while rolling the foil. Preferably the molecules applied to the aluminium surface with the solvent form a graft layer which, at least in the later course, completely cover the surface of the aluminium foil. Complete wetting of the aluminium foil 1 is not required here. More preferably with self-organising molecules, a tight packing is formed on the aluminium foil surface through self organization. After spraying the functional coating onto the surface of the aluminium foil additional treatment steps not shown in the drawing, for example edging and cutting to size can take place. Subsequently the aluminium foil is subjected to heat treatment in heat treatment stations 7 by means of which more preferably the rolling oil is removed from the surface of the aluminium foil 1. Annealing of the aluminium foil need not necessarily take place at this point so that roll-hard coated aluminium foils 1 can also be produced. The heat treatment at the heat treatment stations 7 however can also be used to accelerate or complete grafting on of the molecules applied to the aluminium surface. Through the various chemical compositions that can be applied to the surface of the aluminium foil 1 by way of the spray applicator, the surface of the aluminium foil 1 can be prepared for the various requirements in the further processing of manufacturing, for example composite materials or packaging means immediately following the manufacturing of the aluminium foil 1. Additional unwinding, coating and/or coiling processes for pretreating the aluminium foil for further processing are no longer necessary insofar. Obviously the aluminium foil can also be simply cold rolled to the final thickness and coated according to the invention.

1. A method of manufacturing a coated aluminium foil wherein the aluminium foil is manufactured from a hot strip or a casting strip of aluminium or an aluminium alloy by cold-rolling with or without intermediate annealing and coiled onto a coil, wherein optional annealing of the aluminium foil takes place prior coiling, wherein prior to coiling, one or two-sided coating of the aluminium foil with at least a functional coating takes place.

2. The method according to claim 1, wherein the aluminium foil is doubled during cold rolling and the application of the functional coating of the aluminium foil takes place during or after de-doubling of the aluminium foils.

3. The method according to claim 1, wherein the aluminium foil prior to coiling is edged and cut to size wherein during edging or cutting of the aluminium foil the functional coating of the aluminium foil is applied.

4. The method according to claim 1, wherein the coating of the aluminium foil takes place with the use of a solvent, and that prior to coiling of the aluminium foil at least one heat treatment of the aluminium foil for the removal of the solvent is carried out.

5. The method according to claim 1, wherein the coating of the aluminium foil is applied using a spray or roller applicator.

6. The method according to claim 1, wherein the aluminium foil has a thickness from 2 to 100 μm.

7. The method according to claim 1, wherein a functional coating with adhesion-supporting, release, corrosion protection and/or wetting-supporting characteristics is applied.

8. The method according to claim 1, wherein the characteristics of the coating can be activated subsequently.

9. The method according to claim 1, wherein with the functional coating is formed a graft layer.

10. The method according to claim 1, wherein phosphonic acid or its derivative is used to form the graft layer.

11. An aluminium foil consisting of aluminium or an aluminium alloy with a functional coating manufactured by a method according to claim 1.

12. (canceled)

13. The method according to claim 9, wherein the graft layer includes self-organising molecules.
